(19) United States
(12) Patent Application Publication
(10) Pub. No.: US 2024/0099008 A1
(43) Pub. Date: Mar. 21, 2024

(54) THREE-DIMENSIONAL MEMORY DEVICE AND METHOD OF FORMING THE SAME

(71) Applicant: Yangtze Memory Technologies Co., Ltd., Wuhan (CN)

(72) Inventors: Tingting GAO, Wuhan (CN); ZhiLiang XIA, Wuhan (CN); Xiaoxin LIU, Wuhan (CN); Xiaolong DU, Wuhan (CN); Changzhi SUN, Wuhan (CN); Jiayi LIU, Wuhan (CN); ZongLiang HUO, Wuhan (CN)

(73) Assignee: Yangtze Memory Technologies Co., Ltd., Wuhan (CN)

(21) Appl. No.: 17/945,703

(22) Filed: Sep. 15, 2022

(51) Int. Cl. H01L 27/1157; H01L 27/11582

(52) U.S. Cl. CPC H01L 27/1157; H01L 27/11582

(57) ABSTRACT

According to an aspect of the disclosure, a semiconductor device is provided. The semiconductor device includes a stack structure that includes alternating insulating layers and word line layers. The semiconductor device also includes a first channel structure extending through the stack structure, a first top select gate (TSG) layer over the stack structure, and a second TSG layer over the first TSG layer. The semiconductor device further includes a second channel structure extending through the first and second TSG layers, where the second channel structure is positioned over and coupled to the first channel structure.

### BACKGROUND

The present disclosure relates to memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

The present disclosure describes embodiments generally related to structures and methods of forming the same for a 3D NAND memory device.

According to an aspect of the disclosure, a semiconductor device is provided. The semiconductor device can include a stack structure that includes alternating insulating layers and word line layers. The semiconductor device can include a first channel structure extending through the stack structure, a first top select gate (TSG) layer over the stack structure, and a second TSG layer over the first TSG layer. The semiconductor device can include a second channel structure extending through the first and second TSG layers, where the second channel structure can be positioned over and coupled to the first channel structure.

The semiconductor device can further include a first dielectric layer positioned between the first TSG layer and the second TSG layer.

In some embodiments, the word line layers can include tungsten, and the first and second TSG layers can include polysilicon.

In some embodiments, the first channel structure can include a blocking layer that can extend through the word line layers and the insulating layers, and further into a substrate on which the stack structure is positioned. The first channel structure can also include a charge storage layer formed over the blocking layer, a tunneling layer formed over the charge storage layer, a channel layer formed over the tunneling layer, an isolation layer formed over the channel layer, and a top channel contact formed over the isolation layer and in contact with the channel layer.

In the semiconductor device, the second channel structure can include a gate dielectric layer extending through the first and second TSG layers, and a second channel layer formed along the gate dielectric layer and over the top channel contact, where the second channel layer can be in contact with the top channel contact.

The semiconductor device can further include a separation structure that extends along a direction parallel to the substrate, and extends through the second TSG layer.

The semiconductor device can include a second dielectric layer positioned over the second TSG layer and a third dielectric layer positioned over the second dielectric layer. The second channel structure can further extend through the second and third dielectric layers.

In some embodiments, the separation structure can extend through the first dielectric layer and the first TSG layer.

The semiconductor device can include an array region and a staircase region adjacent to the array region. The first channel structure and the second channel structure can be positioned in the array region. The staircase region can include a plurality of stairs formed in the stack structure and the first and second TSG layers.

In some embodiments, the plurality of stairs can include a first stair formed in the first and second TSG layers. A TSG contact can extend from the first TSG layer and through the first dielectric layer and the second TSG layer at the first stair of the plurality of stairs.

In some embodiments, the plurality of stairs can include a first stair formed in the first TSG layer and a second stair formed in the second TSG layer. A first TSG contact can extend from the first TSG layer at the first stair of the plurality of stairs, and a second TSG contact can extend from the second TSG layer at the second stair of the plurality of stairs.

The semiconductor device can include a fourth dielectric layer formed over the third dielectric layer, and a contact positioned over the second channel structure and extending through the fourth dielectric layer.

In some embodiments, the semiconductor device can include a slit structure extending through the word line layers and the insulating layers and further extending along a direction parallel to the substrate, and a separation structure extending along the direction parallel to the substrate, extending through the second TSG layer, and positioned over the slit structure.

According to another aspect of the disclosure, a method of manufacturing a semiconductor device is provided. In the method, a stack structure of alternating insulating layers and word line layers can be formed over a substrate. A first channel structure can be formed to extend through the insulating layers and the word line layers and into the substrate. A first top select gate (TSG) layer can be formed over the stack structure. A first dielectric layer can be formed over the first TSG layer, and a second TSG layer can be formed over the first dielectric layer. A second channel structure can further be formed over the first channel structure, where the second channel structure can extend through the first TSG layer, the first dielectric layer, and the second TSG layer, and in contact with the first channel structure.

To form the first channel structure, a channel opening can be formed to extend through the insulating layers and the word line layers and further into the substrate. A blocking layer can be formed in the channel opening. A charge storage layer can be formed over the blocking layer, a tunneling layer can be formed over the charge storage layer, a channel layer can be formed over the tunneling layer, an isolation layer can be formed over the channel layer, and a top channel contact can be formed over the isolation layer and in contact with the channel layer.

To form the second channel structure, a gate dielectric layer can be formed to extend through the first TSG layer, the first dielectric layer, and the second TSG layer. A second channel layer can be formed along the gate dielectric layer and over the top channel contact of the first channel structure, a second isolation layer can be formed over the second channel layer, and a second channel contact can be formed over the second isolation layer and in contact with the second channel layer.

In the method, a separation structure can be formed to extend along a direction parallel to the substrate, and further extend through the second TSG layer. A second dielectric layer can be formed over the second TSG layer, and a third dielectric layer can be formed over the second dielectric layer. The second channel structure can further extend through the second and third dielectric layers.

In some embodiments, the separation structure can further extend through the first dielectric layer and the first TSG layer.

In the method, a staircase region can be formed to include a plurality of stairs in the stack structure and the first and second TSG layers.

In an embodiment, when the plurality of stairs includes a stair formed in the first and second TSG layers, a first TSG contact can be formed to extend from the first TSG layer and through the first dielectric layer and the second TSG layer at the stair of the plurality of stairs. In another embodiment, when the plurality of stairs includes a first stair formed in the first TSG layer and a second stair formed in the second TSG layer, the first TSG contact can be formed to extend from the first TSG layer at the first stair of the plurality of stairs and a second TSG contact can be formed to extend from the second TSG layer at the second stair of the plurality of stairs respectively.

According to another aspect of the disclosure, a memory system device can be provided. The memory system can include control circuitry coupled with a memory device. The memory device can include a stack structure that includes alternating insulating layers and word line layers. The memory device can include a first channel structure extending through the stack structure, a first top select gate (TSG) layer over the stack structure, a second TSG layer over the first TSG layer, and a second channel structure. The second channel structure can extend through the first and second TSG layers, and be positioned over and coupled to the first channel structure.

According to yet another aspect of the disclosure, a semiconductor device is provided. The semiconductor device can include a stack structure that is formed of alternating insulating layers and word line layers. The semiconductor device can include a first semiconductor layer over the stack structure, a second semiconductor layer over the first semiconductor layer, and a separation structure extending through the first semiconductor layer.

In some embodiments, the semiconductor device can further include a first dielectric layer positioned between the first semiconductor layer and the second semiconductor layer.

In some embodiments, the word line layers can include tungsten, and the first and second semiconductor layers can include polysilicon.

The semiconductor device can further include a first channel structure extending through the stack structure, and a second channel structure extending through the first semiconductor layer, the first dielectric layer, and the second semiconductor layer. The second channel structure can be positioned over and coupled to the first channel structure.

In some embodiments, the first channel structure can include a blocking layer extending through the word line layers and the insulating layers and further into a substrate on which the stack structure is positioned. The first channel structure can include a charge storage layer formed over the blocking layer, a tunneling layer formed over the charge storage layer, a channel layer formed over the tunneling layer, an isolation layer formed over the channel layer, and a top channel contact formed over the isolation layer and in contact with the channel layer.

In some embodiment, the second channel structure can include a gate dielectric layer extending through the first and second TSG layers, and a second channel layer formed along the gate dielectric layer. The second channel layer can be in contact with the top channel contact.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A is a perspective view of a 3D NAND memory device, in accordance with exemplary embodiments of the disclosure.

FIG. 1B is an expanded view of a channel structure and a top select gate (TSG) channel structure in a 3D NAND memory device, in accordance with exemplary embodiments of the disclosure.

FIG. 2A is a first cross-sectional view of a 3D NAND memory device, in accordance with exemplary embodiments of the disclosure.

FIG. 2B is a second cross-sectional view of a 3D NAND memory device, in accordance with exemplary embodiments of the disclosure.

FIG. 3 is a top down view of a 3D NAND memory device, in accordance with exemplary embodiments of the disclosure.

FIGS. 4-10 are perspective views of various intermediate steps of manufacturing a 3D NAND memory device, in accordance with exemplary embodiments of the disclosure.

FIG. 11 is a flowchart of a process for manufacturing a 3D NAND memory device, in accordance with exemplary embodiments of the disclosure.

FIG. 12 illustrates a block diagram of an exemplary system having a memory device, according to some aspects of the present disclosure.

FIG. 13 illustrates a diagram of an exemplary memory card having a memory device, according to some aspects of the present disclosure.

FIG. 14 illustrates a diagram of an exemplary solid-state drive (SSD) having a memory device, according to some aspects of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a related 3D NAND memory device, a stack of alternating insulating layers and word line layers can be formed over a substrate, where one or more uppermost word line layers in the stack can function as top select gate (TSG) layers, and the word line layers can include tungsten. A plurality of channel structures can extend through the insulating layers and the word line layers to form a plurality of memory cell strings. Each of the memory cell strings can include a plurality of memory cells and one or more top select transistors (TSTs) that are connected in series and formed based on a respective channel structure and the word line layers.

In some implementations of the disclosure, a 3D NAND device can include a stack of alternating insulating layers and word line layers, and a plurality of TSG layers over the stack of the insulating layers and the word line layers. The plurality of TSG layers can include one or more first TSG layers and one or more second TSG layers, where the plurality of TSG layers and the word line layers can include different materials. For example, the plurality of TSG layers can include polysilicon and the word line layers can include tungsten. Accordingly, a plurality of first channel structures can extend through the stack of insulating layers and the word line layers. A plurality of second channel structures can be formed on the first channel structures and extend through the plurality of TSG layers to form a plurality of TSTs. The plurality of TSG layers that include a different material from the word line layers can simplify the manufacturing process and further reduce the manufacturing cost. The one or more first TSG layers can be positioned between the stack of the insulating layers and the word line layers and the one or more second TSG layers. The one or more first TSG layers can function as dummy TSG layers that can help control the voltage change of TSTs and reduce the threshold voltage change of TSTs caused by B diffusion. For example, without the first TSG layer, the B diffusion can happen when a thermal process is introduced in the formation of the second channel structures, where the B can migrate from doped regions (e.g., p-well region in the substrate) to the second TSG layer and/or the second channel structures. When the first TSG layer is introduced, the first TSG layer can function as a blocking layer to prevent the B from diffusing into the second TSG layer and/or the second channel structures. The one or more first TSG layers can also be used as etch stop layers when the one or more second TSG layers are etched by an etching process to form TSG cut structures that divide the one or more second TSG layers into a plurality of sub second TSG layers, where the etch stop layers can improve the etch uniformity of the etching process.

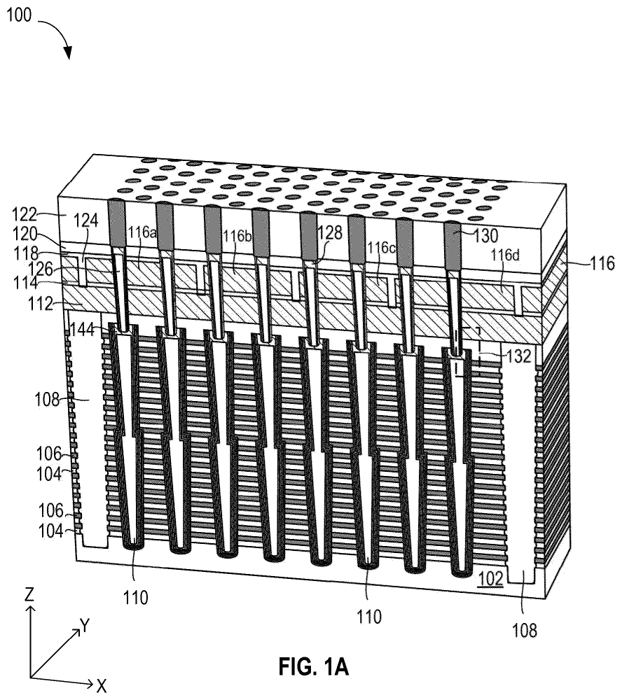

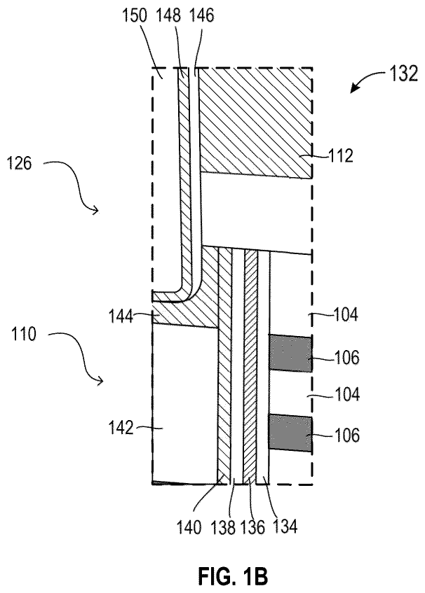

FIG. 1A is a perspective view of a 3D NAND memory device (or device) 100, in accordance with exemplary embodiments of the disclosure. As shown in FIG. 1A, the device 100 can include a stack of alternating insulating layers 104 and word line layers 106 positioned over a substrate 102. In some embodiments, the substrate 102 may be a semiconductor substrate such as a Si substrate. In some embodiments, the substrate 102 can be a sacrificial layer and be removed in future manufacturing steps. In some embodiments, the substrate 102 can be a semiconductor layer, such as a polysilicon layer. In order to form the polysilicon layer, a sacrificial substrate (not shown) can be provided firstly on which the insulating layers 104 and word line layers 106 are formed. The sacrificial substrate can be removed by an etching process, and a deposition process, can be applied to form the polysilicon layer. The insulating layers 104 and the word line layers 106 can extend in both a first direction (or X direction) parallel to the substrate 102 and a second direction (or Y direction) parallel to the substrate 102, where the first direction can be perpendicular to the second direction. The device 100 can include a plurality of first channel structures (or channel structures) 110 extending through the insulating layers 104 and the word line layers 106 and further into the substrate 102. The device 100 can further include a first top select gate (TSG) layer 112 positioned over the stack, a second TSG layer 116 positioned over the first TSG layer 112, and a plurality of second channel structures (or TSG channel structures) 126 that can be positioned on and coupled to the first channel structure 110 and further extend through the first and second TSG layers 112 and 116. The device 100 can further include a first dielectric layer 114 positioned between the first TSG layer 112 and the second TSG layer 116 such that the first TSG layer 112 and the second TSG layer 116 are spaced apart from one another.

The device 100 can also include a plurality of slit structures 108. For example, two slit structures 108 are included in FIG. 1A. In some embodiments, a gate-last fabrication technology is used to form the device 100. Thus, an initial stack of alternating insulating layers (e.g., 104) and sacrificial layers (not shown) can be formed over the substrate 102. The slit structures 108 are subsequently formed to assist in the removal of the sacrificial word line layers, and the formation of the actual word line layers (e.g., 106). In some embodiments, the slit structures 108 can function as common sources. Thus, each of the slit structures 108 can include a dielectric spacer (not shown) that extends through the insulating layers 104 and the word line layers 106, and a conductive layer formed along the dielectric spacer. In some embodiments, the slit structures 108 can be dielectric structures to divide the device 100 into several regions.

The device 100 can further include a plurality of separation structures (or TSG cut structures) 124 that can have a trench profile and extend along the second direction (or Y direction) parallel to the substrate 102, and further extend through the second TSG layer 116 such that the second TSG layer 116 is divided by the separation structures 124. The device 100 can include a second dielectric layer 118 positioned over the second TSG layer 116 and a third dielectric layer 120 positioned over the second dielectric layer 118. The second channel structures 126 can further extend through the second and third dielectric layers 118 and 120.

In some embodiments, the separation structures 124 may further extend through the first dielectric layer 114. In some embodiments, the separation structures 124 can extend through both the first dielectric layer 114 and the first TSG layer 112 such that the first TSG layer 112 can also be divided by the separation structures 124.

In the disclosure, the first TSG layer 112 can function as a dummy TSG layer, and the second TSG layer 116 can function as a TSG layer. The dummy TSG layer and the TSG layer can be coupled to the second channel structures 126 to form dummy TSTs and TSTs respectively. The TSTs are positioned at drain sides of the memory cell strings and function as switches at the drain sides during the operation (e.g., programming, erasing, or reading) of the memory cell strings. The dummy TSTs can function as additional switches at the drain side. In addition, the first TSG layer 112, which functions as the dummy TSG layer, can help control the voltage change of TSTs and avoid the threshold voltage change of TSTs caused by boron diffusion during manufacturing. The dummy TSG layer (e.g., 112) can also be used as an etch stop layer when the TSG layer (e.g., 116) is etched by an etching process to form the separation structures 124, where the etch stop layer can improve the etch uniformity of the etching process.

The device 100 can include a fourth dielectric layer 122 formed over the third dielectric layer 120 and a plurality of contacts 130 extending from the second channel structures 126 and through the fourth dielectric layer 122. The contacts 130 can further be connected to backend of line (BEOL) metal layers (not shown) on which bias voltages can be applied to operate the second channel structures 126 and the first channel structures 110.

Still referring to FIG. 1A, a plurality of memory cell strings can be formed based on the first channel structures 110, the second channel structures 126, the word line layers 106, and the first and second TSG layers 112 and 116. Each of the memory cell strings can include memory cells that are formed based on the a respective first channel structure 110 and the word line layers 106, a dummy TST that is formed based on a respective second channel structure 126 and the first TSG layer 112, and a TST that is formed based on a respective second channel structure 126 and the second TSG layer 116. The memory cells, the dummy TST, and the TST are disposed sequentially and in series over the substrate 102 along a vertical direction (e.g., Z direction).

The separation structures (or TSG cut structures) 124 can divide the second TSG layer 116 into a plurality of sub TSG layers. For example, four sub TSG layers 116a-116d are provided in FIG. 1A. As shown in FIG. 1A, in some embodiments, the separation structures 124 can be positioned over the word line layers 106 and adjacent to the second channel structures 126. In some embodiments, the separation structures 124 can be positioned over the slit structures 108. Accordingly, the device 100 can be divided into a plurality of sections based on the sub TSG layers, where each of the sections can include a respective sub TSG layer and the second channel structures that are coupled to the respective sub TSG layer. Thus, the sections can be operated independently by applying appropriate control voltages on the sub TSG layers.

It should be noted that FIG. 1A is just an exemplary embodiment. The device 100 can include one or more dummy TSG layers (e.g., 112) that are positioned over the stack of the insulating layers and word line layers, and one or more TSG layers (e.g., 116). The one or more TSG layers can be positioned over the one or more dummy TSG layers, and divided by the separation structures (or TSG cut structures) 124.

In some embodiments, the word line layers 106 and the first and second TSG layers 112 and 116 can include different materials. For example, the word line layers 106 can include tungsten, and the first and second TSG layers 112 and 116 can include polysilicon. The insulating layer 104 can include SiO. The first dielectric layer 114, the second dielectric layer 118, the third dielectric layer 120, the fourth dielectric layer 122, and the separation structures (or TSG cut structures) 124 can include any suitable dielectric materials, such as SiO, SIN, SICN, SION, SIC, SiCON, the like, or a combination thereof. The contacts 130 can include a conductive material, such as TiN. Ta, TaN. W, Co, Ru, Al, Cu, the like, or a combination thereof.

FIG. 1B is an expanded view of a first channel structure 110 and a second channel structure 126. As shown in FIG. 1B, the first channel structures 110 can include a blocking layer 134 extending through the insulating layers 104 and the word line layers 106. The first channel structure 110 can include a charge storage layer 136 formed over the blocking layer 134, a tunneling layer 138 formed over the charge storage layer 136, and a channel layer 140 formed over the tunneling layer 138. The first channel structure 110 can further include an isolation layer 142 formed over the channel layer 140, and a top channel contact 144 formed over the isolation layer 142 and in contact with the channel layer 140.

The second channel structure 126 can include a gate dielectric layer 146 extending through the first TSG layer 112, the first dielectric layer 114, and the second TSG layer 116, and positioned over the top channel contact 144 of the first channel structure 110. The second channel structure 126 can include a second channel layer 148 formed along the gate dielectric layer 146 and over top channel contact 144. The second channel layer 148 can further be in contact with the top channel contact 144. The second channel structure 126 can include a second isolation layer 150 formed over the second channel layer 148. The second channel structure 126 can further include a second channel contact 128 (shown in FIG. 1A) formed over the second isolation layer 150 and in contact with the second channel layer 148.

In some embodiments, the blocking layer 134, the tunneling layer 138, the isolation layer 142, and the second isolation layer 150 can include a same composition such as SiO. The gate dielectric layer 146 can be a SiO layer or a high-k layer. The charge storage layer 136 can be a SiN layer. The channel layer 140, the top channel contact 144, the second channel contact 128, and the second channel layer 148 can include a same composition such as polysilicon.

The first channel structures 110 and the second channel structures 126 can have a cylindrical shape. However, the present disclosure is not limited thereto, and the first channel structures 110 and second channel structures 126 may be formed in other shapes, such as a square pillar-shape, an oval pillar-shape, or any other suitable shapes.

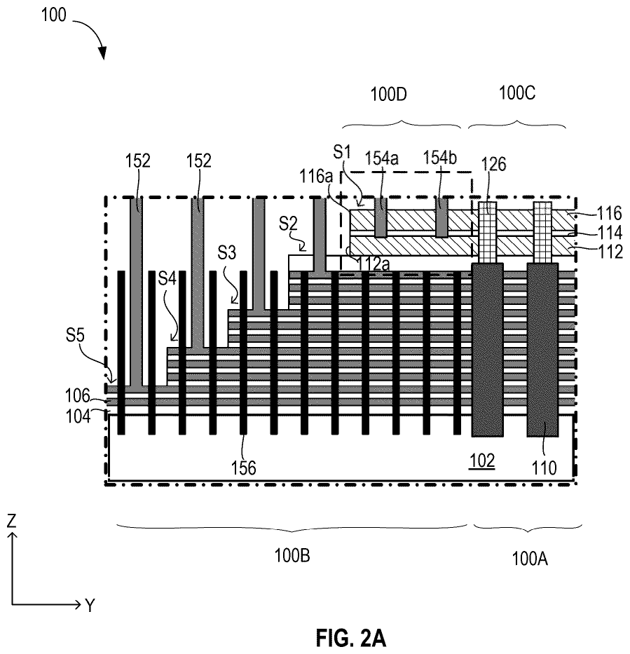

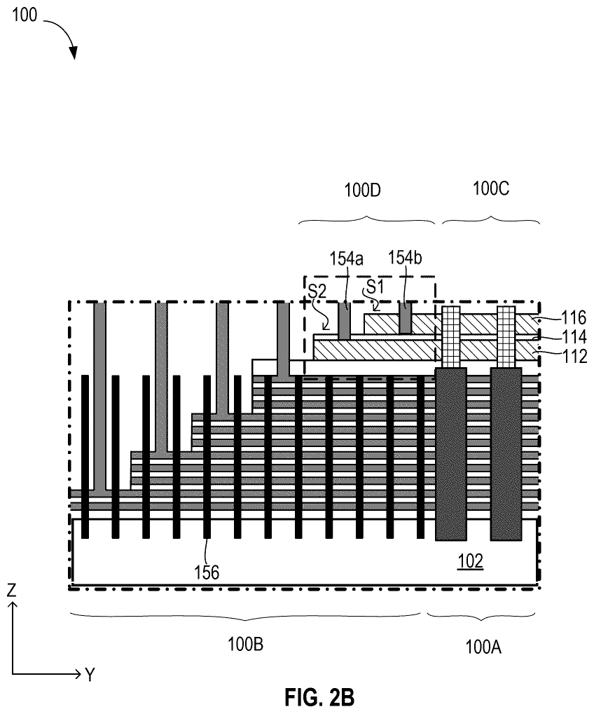

FIG. 2A shows a first exemplary cross-sectional view of the device 100 and FIG. 2B shows a second exemplary cross-sectional view of the device 100. As shown in FIG. 2A, the stack of insulating layers 104 and the word line layers 106 can include a staircase region 100B and an array region 100A. The first channel structures 110 can extend through the insulating layers 104 and the word line layers 106 at the array region 100A. The staircase region 100B of the stack of insulating layers 104 and the word line layers 106 can include a plurality of stairs, and each of the plurality of stairs can include a respective pair of the word line layer 106 and the insulating layer 104. A plurality of word line contacts 152 can extend from the plurality of stairs.

Still referring to FIG. 2A, the first TSG layer 112 and the second TSG layer 116 can further include a TSG staircase region 100D and a TSG array region 100C, where the TSG staircase region 100D is positioned over the staircase region 100B of the stack of insulating layers 104 and the word line layers 106, and the TSG array region 1000 is positioned over the array region 100A of the stack of insulating layers 104 and the word line layers 106. The second channel structures 126 can be positioned in the TSG array region 100C and further extend from the first channel structures 110. For clarity and simplicity, details of the first channel structures 110 and the second channel structures 126 are not provided in FIGS. 2A and 2B.

In an embodiment, as shown in FIG. 2A, the TSG staircase region 100D can include a stair S1, and the staircase region 100B of the stack of insulating layers 104 and the word line layers 106 can include stairs S2-S5. A side portion 112a of the first TSG layer 112 and a side portion 116a of the second TSG layer 116 can be aligned at the TSG staircase region 100D. The device 100 can include a plurality of TSG contacts (e.g., 154a and 154b) extending from the first TSG layer 112, and further through the first dielectric layer 114 and the second TSG layer 116 at the stair S1 of the TSG staircase region 100D.

In another embodiment, as shown in FIG. 2B, the TSG staircase region 100D can include a first stair S1 and a second stair S2. Accordingly, a first TSG contact 154a can extend from the first TSG layer 112 at the first stair of the TSG staircase region 100D and a second TSG contact 154b can extend from the second TSG layer 116 at the second stair of the TSG staircase region 100D.

It should be noted that a plurality of dummy channel structures 156 can extend from the substrate 102, and further through the insulating layers 104 and the word line layers 106 both at the staircase region 100B and the array region 100A. The dummy channel structures 156 can serve as sustain components to support the staircase region 100B and/or the array region 100A when the sacrificial layers (not shown) are removed to form the word line layers 106. In an embodiment of FIGS. 2A and 2B, the dummy channel structures 156 are formed with the first channel structures 110 together and have a similar structure to the first channel structures 110. Thus, the dummy structures can also include a blocking layer, a charge storage layer, a tunneling layer, and a channel layer. In another embodiment, the dummy channel structures 156 have a structure that is different from the first channel structures 110. For example, the dummy channel structures 156 can include a dielectric material, such as SiO, SiN, or other suitable dielectric materials.

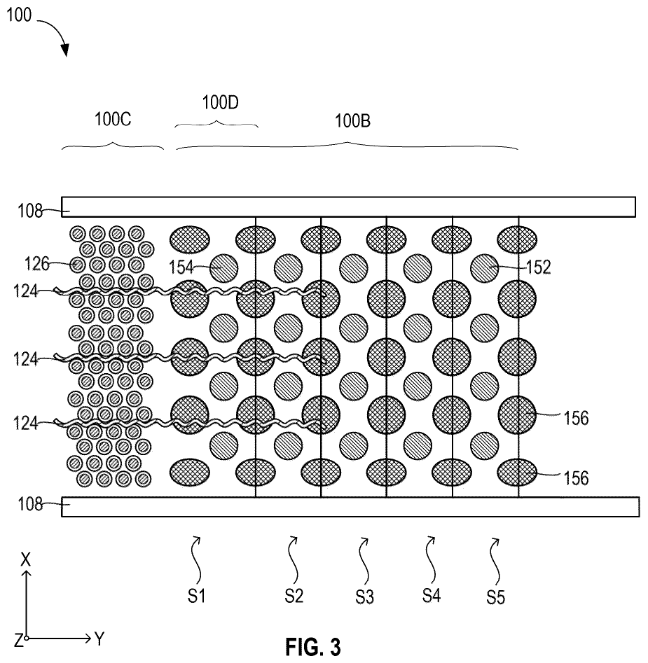

FIG. 3 is a top down view of the device 100. As shown in FIG. 3, the device 100 can include the TSG array region 100C over the array region 100A of the stack and a TSG staircase region 100D over the staircase region 100B of the stack. The TSG staircase region 100D can include a stair S1, and the staircase region 100B of the stack can include stairs S2-S5. The device can include the second channel structures 126 positioned in the TSG array region 100C, TSG contacts 154 positioned in the TSG staircase region 100D, word line contacts 152 positioned in the staircase region 100B of the stack, and the dummy channel structures 156. In addition, the slit structures 108 can be formed to extend along the Y direction and further through the TSG array region 100C and the array region 100A of the stack along the Z direction. The separation structures 124 can extend along the Y direction and further through the TSG array region 100C and the array region 100A of the stack along the Z direction to divide the first and second TSG layers into sub TSG layers. In some embodiments, the separation structures 124 can further be positioned over the slit structures 108 and extend along the Y direction.

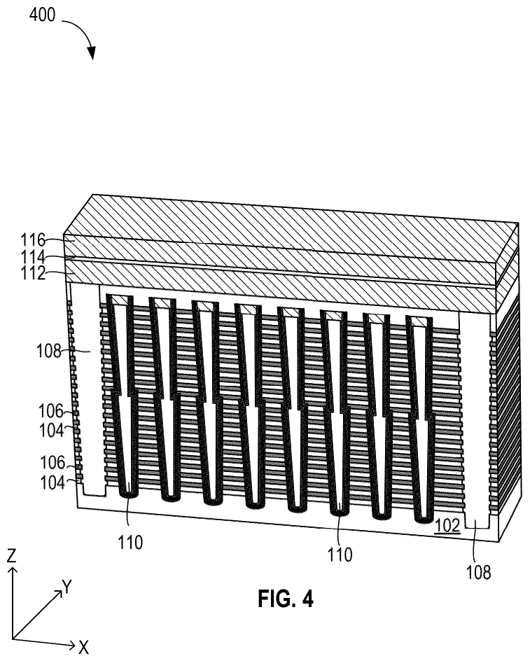

FIGS. 4-10 are perspective views of various intermediate steps of manufacturing a 3D NAND memory device, in accordance with exemplary embodiments of the disclosure. As shown in FIG. 4, a semiconductor structure 400 can be formed firstly. In the semiconductor structure 400, a stack of alternating insulating layers 104 and word line layers 106 can be formed over a substrate 102. A plurality of first channel structures 110 can be formed to extend through the insulating layers 104 and the word line layers 106 and further into the substrate 102. In addition, a plurality of slit structures 108 can be formed to extend through the insulating layers 104 and the word line layers 106 and further into the substrate 102. The slit structures 108 can further extend along a direction (e.g., Y direction) parallel to the substrate 102. In some embodiments, in order to form the word line layers 106, an initial stack of alternating insulating layers (e.g., 104) and sacrificial layers (not shown) can be formed. The sacrificial layers can further be replaced by a conductive material, such as tungsten, to form the word line layers 106.

Still referring to FIG. 4, a first TSG layer 112 can be formed over the stack of alternating insulating layers 104 and word line layers 106, a first dielectric layer 114 can be formed over the first TSG layer 112, and a second TSG layer 116 can be formed over the first dielectric layer 114.

In order to form the semiconductor structure 400, various semiconductor manufacturing processes can be applied. The semiconductor manufacturing processes can include a deposition process that can include a chemical vapor deposition (CVD), a physical vapor deposition (PVD), a sputtering, an epitaxial deposition, an atomic layer deposition (ALD), or the like. The semiconductor manufacturing processes can also include an etching process, such as a wet etching or a dry etching. The semiconductor process can further include a photolithographie process, an ion implantation process, a metrology process, an inline parametric characterization process, an inline defect characterization process, and so on.

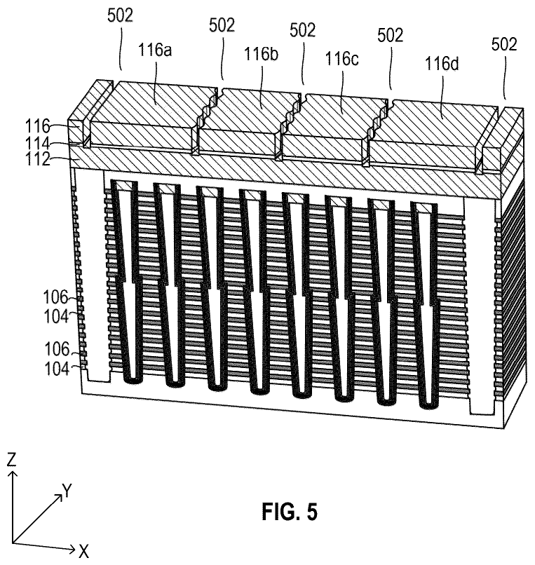

In FIG. 5, a plurality of trenches 502 can be formed in the second TSG layer 116 to divide the second TSG layer 116 into a plurality of sub TSG layers (e.g., 116a-116d). In an embodiment, the first TSG layer 112 can function as an etch stop layer, and the trenches 502 can extend through the first dielectric layer 114 and land on the first TSG layer 112. In another embodiment, the trenches 502 can also extend through the first TSG layer 112. In order to form the trenches 502, a photolithography process can be applied to form a mask layer (not shown) with patterns. An etching process can subsequently be applied to transfer the patterns into the second TSG layer 116 to form the trenches 502. As mentioned above, by introducing the first TSG layer 112 to serve as an etch stop layer, an etch uniformity of the etching process can be improved when the second TSG layer (e.g., 116) are etched by the etching process to form trenches 502.

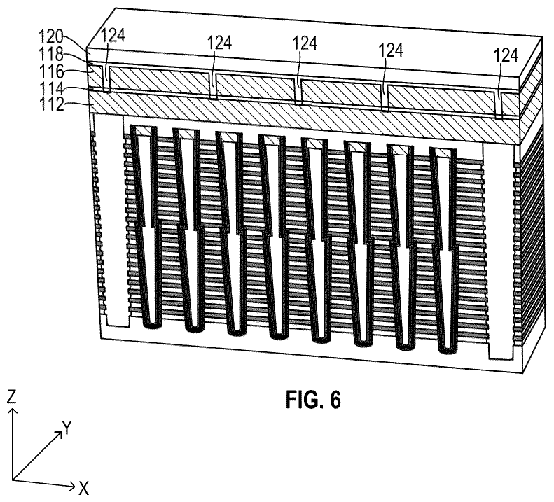

In FIG. 6, a dielectric material can be deposited into the trenches 502 to form separation structures 124. The dielectric material can further be deposited over the second TSG layer 116 to form a second dielectric layer 118. In some embodiments, a surface planarization process, such as a mechanical chemical polishing (CMP) process, can be applied to flatten the second dielectric layer 118. Further, a third dielectric layer 120 can be formed over the second dielectric layer 118. In an exemplary embodiment of FIG. 6, the separation structures 124 and the second dielectric layer 118 can include a same composition such as SiO, and the third dielectric layer 120 can include SiN. The separation structures 124, the second dielectric layer 118, and the third dielectric layer 120 can be formed by any suitable deposition processes, such as a chemical vapor deposition (CVD), a physical vapor deposition (PVD), an atomic layer deposition (ALD), a thermal oxidation, an e-beam evaporation, a sputtering, a diffusion, or any combination thereof.

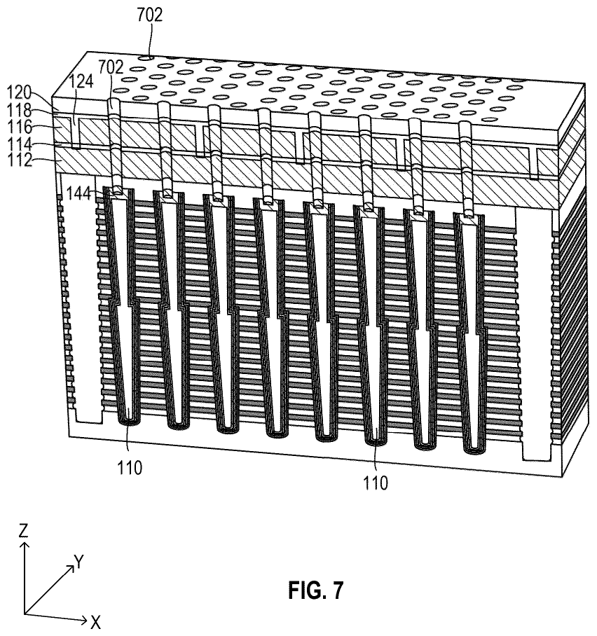

In FIG. 7, a plurality of TSG channel holes 702 can be formed by a patterning process that can include a photolithography process and an etching process. The TSG channel holes 702 can extend through the third dielectric layer 120, the second dielectric layer 118, the second TSG layer 116, the first dielectric layer 114, and the first TSG layer 112, and further land on the top channel contact 144 of the first channel structures 110. In some embodiments, the etching process can introduce an over etch step to recess the top channel contacts 144, and the TSG channel holes 702 can accordingly extend into the top channel contacts 144.

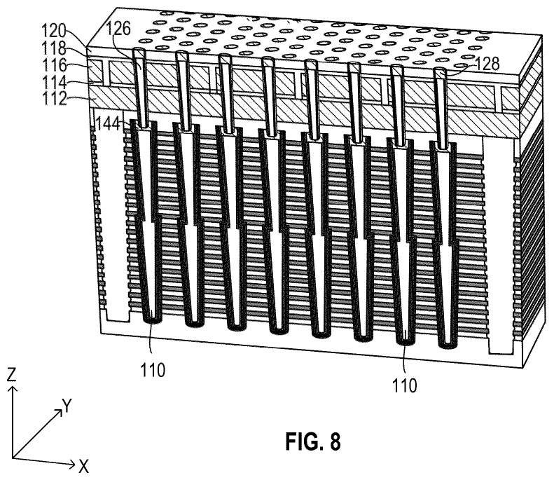

In FIG. 8, a plurality of second channel structures 126 can be formed in the TSG channel holes 702. The second channel structures 126 can extend through the third dielectric layer 120, the second dielectric layer 118, the second TSG layer 116, the first dielectric layer 114, and the first TSG layer 112. To form a second channel structure 126, a gate dielectric layer (e.g., 146) can be formed in a TSG channel hole 702. Further, a bottom portion of the gate dielectric layer 146 can be removed by an etching process, and a second channel layer (e.g., 148) can be formed along the gate dielectric layer and over the top channel contact 144. The second channel layer (e.g., 148) can further be in contact with the top channel contact 144. A second isolation layer (e.g., 150) can be formed over the second channel layer, and a second channel contact (e.g., 128) can be formed over the second isolation layer and in contact with the second channel layer.

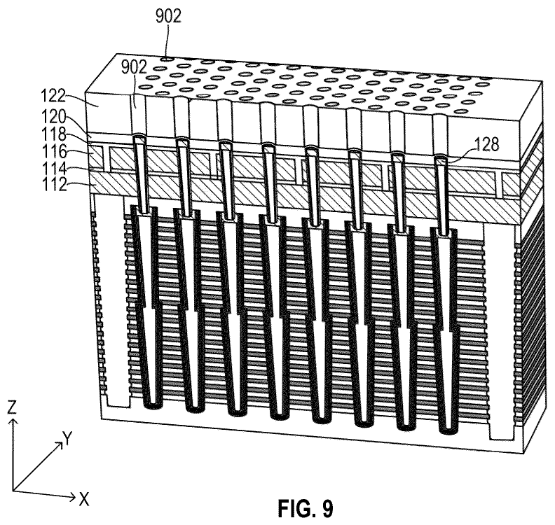

In FIG. 9, a fourth dielectric layer 122 can be formed over the third dielectric layer 120 and a plurality of contact openings 902 can further be formed in the fourth dielectric layer 122 through a combination of a photolithography process and an etching process. The contact openings 902 can be formed to expose the second channel contacts 128.

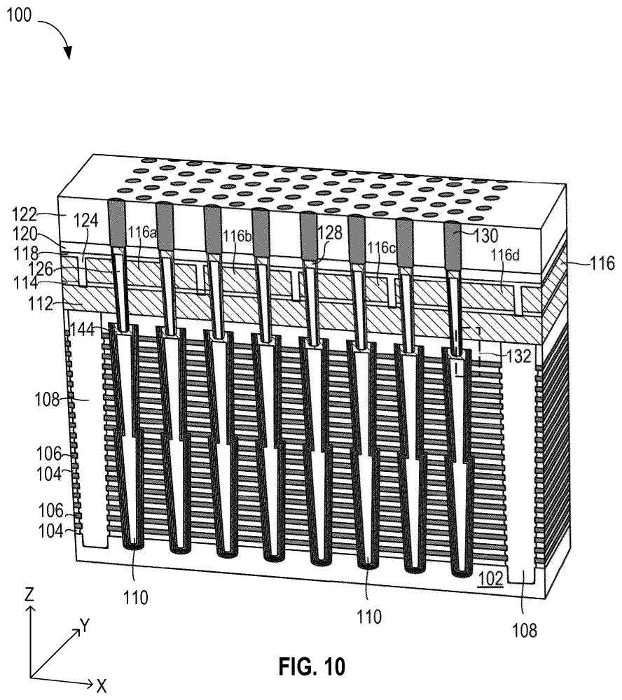

In FIG. 10, a conductive material can be deposited to fill in the contact openings 902. Further, a CMP process can be applied to remove any extra conductive material positioned on the fourth dielectric layer 122, and the conductive material that remains in the contact openings 902 becomes the contacts 130. The contacts 130 can further be connected to backend of line (BEOL) metals (not shown) on which bias voltages can be applied to operate the second channel structures 126 and the first channel structures 110. In some embodiments, the conductive materials can include W, Co, Ru, Al, Cu, or the like. In some embodiments, a barrier layer, such as TIN, Ta, or TaN, can be deposited between the fourth dielectric layer 122 and the conductive material.

Still referring to FIG. 10, a 3D NAND memory device (or device) 100 can be formed upon the formation of the contacts 130, which can be identical to the device 100 illustrated in FIG. 1A. For example, in the device 100 of FIG. 10, the stack of alternating insulating layers 104 and word line layers 106 can be formed over the substrate 102. The first channel structures 110 can extend from the substrate 102 and further through the insulating layers 104 and the word line layers 106. The first TSG layer 112 can be formed over the stack, the first dielectric layer 114 can be formed over the first TSG layer 112, and the second dielectric layer 116 can be formed over the first dielectric layer 114. The second channel structures 126 can be positioned over the first channel structures 110 and further extend through the first TSG layer 112, the first dielectric layer 114, and the second TSG layer 116. The first channel structures 110 and the second channel structures 126 can be coupled to the word line layers 106, and the first TSG layer 112 and second TSG layer 116 respectively to form a plurality vertical memory cell strings.

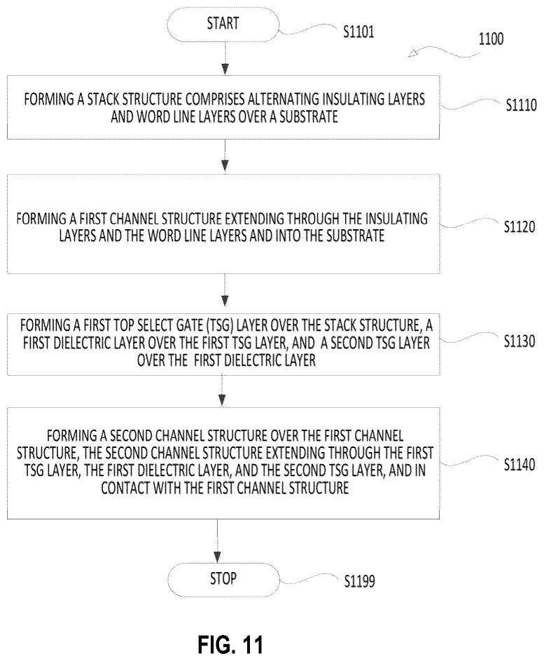

FIG. 11 is a flowchart of an exemplary process 1100 for fabricating a 3D NAND memory device. The process 1100 begins at S1101, and then proceeds to S1110. At S1110, a stack structure that includes alternating insulating layers and word line layers can be formed over a substrate.

At S1120, a first channel structure can be formed to extend through the insulating layers and the word line layers and into the substrate.

At S1130, a first TSG layer can be formed over the stack structure. A first dielectric layer can be formed over the first TSG layer, and a second TSG layer can be formed over the first dielectric layer. In some embodiments. S1110, S1120, and S1130 can be performed as illustrated with reference to FIG. 4.

The process 1100 can then proceed to S1140, where a second channel structure can further be formed over the first channel structure. The second channel structure can extend through the first TSG layer, the first dielectric layer, and the second TSG layer, and in contact with the first channel structure. In some embodiments, S1140 can be performed as illustrated with reference to FIGS. 7 and 8.

To form the first channel structure, a channel opening can be formed to extend through the insulating layers and the word line layers and further into the substrate. A blocking layer can be formed in the channel opening. A charge storage layer can be formed over the blocking layer, a tunneling layer can be formed over the charge storage layer, a channel layer can be formed over the tunneling layer, an isolation layer can be formed over the channel layer, and a top channel contact can be formed over the isolation layer and positioned in contact with the channel layer.

To form the second channel structure, a gate dielectric layer can be formed to extend through the first TSG layer, the first dielectric layer, and the second TSG layer. A second channel layer can be formed along the gate dielectric layer and over the top channel contact of the first channel structure, a second isolation layer can be formed over the second channel layer, and a second channel contact can be formed over the second isolation layer and in contact with the second channel layer.

In the process 1100, as shown in FIGS. 5 and 6, a separation structure can be formed to extend along a direction parallel to the substrate, and further extend through the second TSG layer. A second dielectric layer can be formed over the second TSG layer, and a third dielectric layer can be formed over the second dielectric layer. The second channel structure can further extend through the second and third dielectric layers.

In some embodiments, the separation structure can further extend through the first dielectric layer and the first TSG layer.

In some embodiments, as shown in FIGS. 2A and 2B, a staircase region can be formed to include a plurality of stairs in the stack structure and the first and second TSG layers.

In an embodiment, as shown in FIG. 2A, when the plurality of stairs includes a stair formed in the first and second TSG layers, a first TSG contact can be formed to extend from the first TSG layer and through the first dielectric layer and the second TSG layer at the stair of the plurality of stairs. In another embodiment, as shown in FIG. 2B, when the plurality of stairs includes a first stair formed in the first TSG layer and a second stair formed in the second TSG layer, the first TSG contact can be formed to extend from the first TSG layer at the first stair of the plurality of stairs and a second TSG contact can be formed to extend from the second TSG layer at the second stair of the plurality of stairs respectively.

It should be noted that additional steps can be provided before, during, and after the process 1100, and some of the steps described can be replaced, eliminated, or performed in different order for additional embodiments of the process 1100. In subsequent process steps, various additional interconnect structures (e.g., metallization layers having conductive lines and/or VIAs) may be formed over the 3D NAND memory device (e.g., 100). Such interconnect structures electrically connect the 3D NAND memory device with other contact structures and/or active devices to form functional circuits. Additional device features such as passivation layers, input/output structures, and the like may also be formed.

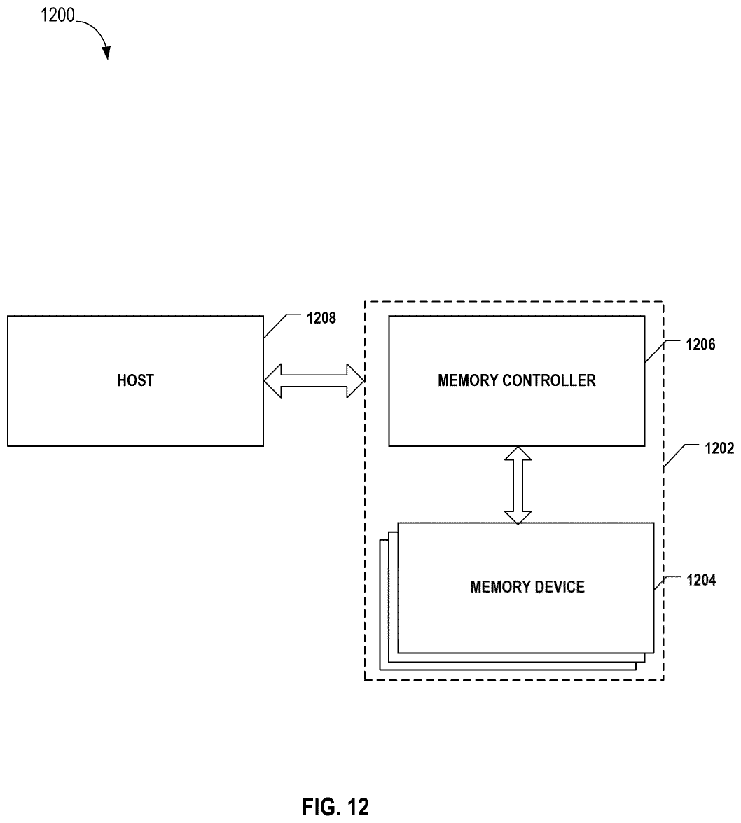

FIG. 12 illustrates a block diagram of an exemplary system 1200 having a memory device, according to some aspects of the present disclosure. The system 1200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 12, the system 1200 can include a host 1208 and a memory system 1202 having one or more memory devices 1204 and a memory controller 1206. The host 1208 can be a processor of an electronic device, such as a central processing unit (CPU), or a system-on-chip (SoC), such as an application processor (AP). The host 1208 can be configured to send or receive data to or from the one or more memory devices 1204.

The one or more memory devices 1204 can be any memory device disclosed in the present disclosure, such as the 3D NAND memory device 100 shown in FIG. 1A, where the device 100 can include one or more TSG layers and one or more dummy TSG layers under the one or more TSG layers. The TSG layers can be made of polysilicon to simplify the manufacturing process and further reduce the manufacturing cost. The dummy TSG layers in the stack of TSG layers can control the voltage change of TSTs so as to reduce the threshold voltage change of TSTs caused by boron diffusion.

The memory controller 1206 is coupled to the one or more memory devices 1204 and the host 1208 and is configured to control the one or more memory devices 1204, according to some implementations. The memory controller 1206 can manage the data stored in the one or more memory devices 1204 and communicate with the host 1208. In some implementations, the memory controller 1206 is designed for operating in a low duty-cycle environment like secure digital (SD) cards, compact flash (CF) cards, universal serial bus (USB) Flash drives, or other media for use in electronic devices, such as personal computers, digital cameras, mobile phones, etc. In some implementations, the memory controller 1206 is designed for operating in a high duty-cycle environment SSDs or embedded multi-media-cards (eMMC's) used as data storage for mobile devices, such as smartphones, tablets, laptop computers, etc., and enterprise storage arrays. The memory controller 1206 can be configured to control operations of the one or more memory devices 1204, such as read, erase, and program operations. As mentioned above, the one or more memory devices 1204 can be the device 100 shown in FIG. 1A. Accordingly, the memory controller 1206 is configured to control operation of the device 100 shown in FIG. 1A, such as read, erase, and program operations.

The memory controller 1206 can also be configured to manage various functions with respect to the data stored or to be stored in the one or more memory devices 1204 including, but not limited to bad-block management, garbage collection, logical-to-physical address conversion, wear leveling, etc. In some implementations, the memory controller 1206 is further configured to process error correction codes (ECCs) with respect to the data read from or written to the one or more memory devices 1204. Any other suitable functions may be performed by the memory controller 1206 as well, for example, formatting the one or more memory devices 1204. The memory controller 1206 can communicate with an external device (e.g., the host 1208) according to a particular communication protocol. For example, the memory controller 1206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a firewire protocol, etc.

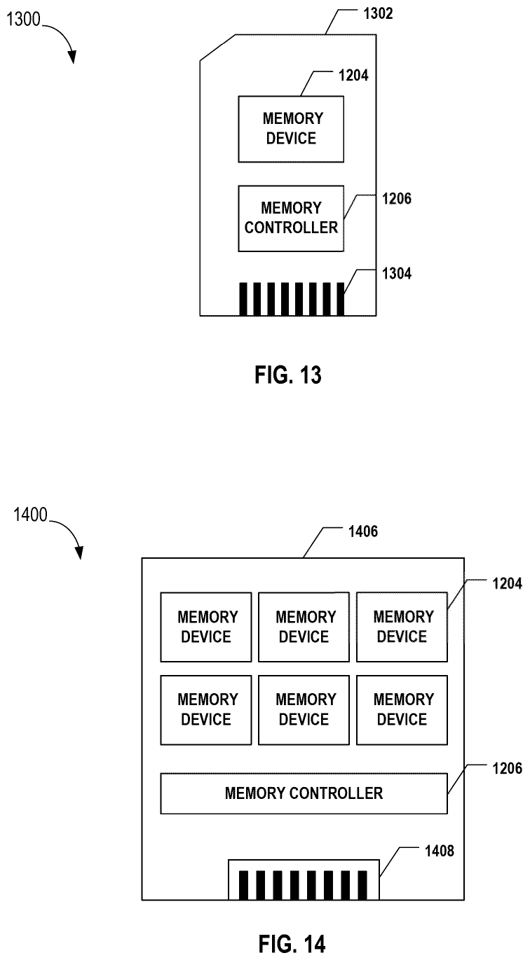

The memory controller 1206 and the one or more memory devices 1204 can be integrated into various types of storage devices, for example, be included in the same package, such as a universal flash storage (UFS) package or an eMMC package. That is, the memory system 1202 can be implemented and packaged into different types of end electronic products. In one example as shown in FIG. 13, the memory controller 1206 and a single memory device 1204 may be integrated into a memory card 1302. The memory card 1302 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 1302 can further include a memory card connector 1304 configured to couple memory card 1302 to a host (e.g., the host 1208 in FIG. 12). In another example as shown in FIG. 14, the memory controller 1206 and multiple memory devices 1204 may be integrated into an SSD 1406. The SSD 1406 can further include an SSD connector 1408 configured to couple SSD 1406 to a host (e.g., the host 1208 in FIG. 12). In some implementations, the storage capacity and/or the operation speed of the SSD 1406 is greater than those of the memory card 1302.

The various embodiments described herein offer several advantages over related examples. In the disclosure, a 3D NAND memory device can include a stack of alternating insulating layers and word line layers over a substrate, and a plurality of TSG layers over the stack of the insulating layers and the word line layers. The TSG layers can include one or more first TSG layers and one or more second TSG layers, where the one or more first TSG layers are positioned between the stack and the one or more second TSG layers. A plurality of first channel structures can extend through the word line layers and insulating layers. A plurality of second channel structures can be positioned over the first channel structures and extend through the TSG layers to form a plurality of TSTs. The TSG layers can be made of polysilicon to simplify the manufacturing process and further reduce the manufacturing cost. The one or more first TSG layers of the TSG layers can control the voltage change of TSTs so as to avoid the threshold voltage change of TSTs caused by boron diffusion. The one or more first TSG layers of the TSG layers can also be used as an etch stop layer to improve an etch uniformity of an etching process when the one or more second TSG layers are etched by the etching process to form TSG cut structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a stack structure comprises alternating insulating layers and word line layers;
a first channel structure extending through the stack structure;
a first top select gate (TSG) layer over the stack structure;
a second TSG layer over the first TSG layer; and
a second channel structure extending through the first and second TSG layers, the second channel structure being positioned over and coupled to the first channel structure.

2. The semiconductor device according to claim 1, further comprising:
a first dielectric layer positioned between the first TSG layer and the second TSG layer.

3. The semiconductor device according to claim 1, wherein the word line layers comprise tungsten, and the first and second TSG layers comprise polysilicon.

4. The semiconductor device according to claim 1, wherein the first channel structure further comprises:
a blocking layer extending through the word line layers and the insulating layers and further into a substrate on which the stack structure is positioned;
a charge storage layer formed over the blocking layer;
a tunneling layer formed over the charge storage layer;
a channel layer formed over the tunneling layer;
an isolation layer formed over the channel layer; and
a top channel contact formed over the isolation layer and in contact with the channel layer.

5. The semiconductor device according to claim 4, wherein the second channel structure further comprises:
a gate dielectric layer extending through the first and second TSG layers; and
a second channel layer formed along the gate dielectric layer and over the top channel contact, the second channel layer being in contact with the top channel contact.

6. The semiconductor device according to claim 5, further comprising:
a separation structure extending along a direction parallel to the substrate, and extending through the second TSG layer.

7. The semiconductor device according to claim 1, further comprising:
a second dielectric layer positioned over the second TSG layer; and
a third dielectric layer positioned over the second dielectric layer, wherein the second channel structure further extends through the second and third dielectric layers.

8. The semiconductor device according to claim 6, wherein the separation structure further extends through a first dielectric layer and the first TSG layer,

9. The semiconductor device according to claim 2, further comprising:
an array region and a staircase region adjacent to the array region, wherein:
the first channel structure and the second channel structure are positioned in the array region, and
the staircase region includes a plurality of stairs.

10. The semiconductor device according to claim 9, wherein the plurality of stairs comprises a first stair formed in the first and second TSG layers, the semiconductor device further comprising:
a TSG contact extending from the first TSG layer and through the first dielectric layer and the second TSG layer at the first stair of the plurality of stairs.

11. The semiconductor device according to claim 9, wherein the plurality of stairs comprises a first stair formed in the first TSG layer and a second stair formed in the second TSG layer, the semiconductor device further comprising:
a first TSG contact extending from the first TSG layer at the first stair of the plurality of stairs; and
a second TSG contact extending from the second TSG layer at the second stair of the plurality of stairs.

12. The semiconductor device according to claim 7, further comprising:
a fourth dielectric layer formed over the third dielectric layer; and
a contact positioned over the second channel structure and extending through the fourth dielectric layer.

13. The semiconductor device according to claim 4, further comprising:
a slit structure extending through the word line layers and the insulating layers and further extending along a direction parallel to the substrate; and
a separation structure extending along the direction parallel to the substrate, extending through the second TSG layer, and positioned over the slit structure.

14. A method of manufacturing a semiconductor device, comprising:
forming a stack structure comprises alternating insulating layers and word line layers;
forming a first channel structure extending through the insulating layers and the word line layers;
forming a first top select gate (TSG) layer over the stack structure;
forming a first dielectric layer over the first TSG layer;
forming a second TSG layer over the first dielectric layer; and
forming a second channel structure over the first channel structure, the second channel structure extending through the first TSG layer, the first dielectric layer, and the second TSG layer, and in contact with the first channel structure.

15. The method according to claim 14, wherein the forming the first channel structure further comprises:
forming a channel opening extending through the insulating layers and the word line layers and further into a substrate;
forming a blocking layer in the channel opening;
forming a charge storage layer over the blocking layer;
forming a tunneling layer over the charge storage layer;
forming a channel layer over the tunneling layer;
forming an isolation layer over the channel layer; and
forming a top channel contact over the isolation layer and in contact with the channel layer.

16. The method according to claim 15, wherein forming the second channel structure further comprises:
forming a gate dielectric layer extending through the first TSG layer, the first dielectric layer, and the second TSG layer;
forming a second channel layer along the gate dielectric layer and over the top channel contact of the first channel structure;
forming a second isolation layer over the second channel layer; and
forming a second channel contact over the second isolation layer and in contact with the second channel layer.

17. The method according to claim 14, furthering comprising:
forming a separation structure extending along a direction parallel to a substrate, and extending through the second TSG layer;
forming a second dielectric layer over the second TSG layer; and
forming a third dielectric layer over the second dielectric layer, wherein the second channel structure further extends through the second and third dielectric layers.

18. The method according to claim 17, wherein the separation structure further extends through the first dielectric layer and the first TSG layer.

19. The method according to claim 14, further comprising:
forming a staircase region that comprises a plurality of stairs in the stack structure and the first and second TSG layers.

20. A semiconductor device, comprising:
a stack structure comprises alternating insulating layers and word line layers;
a first semiconductor layer over the stack structure;
a second semiconductor layer over the first semiconductor layer; and
a separation structure extending through the second semiconductor layer.
